(19) United States
(12) Patent Application Publication
(10) Pub. No.: US 2026/0331193 A1
(43) Pub. Date: Oct. 22, 2026

(54) SOLID STATE MEMORY DEVICE, INFORMATION PROCESSING SYSTEM AND DATA PROCESSING METHOD

(71) Applicant: Lenovo Japan LLC, Tokyo (JP)

(72) Inventors: Yusuke Taira, Kanagawa (JP); Rucha Boid, Kanagawa (JP)

(73) Assignee: Lenovo Japan LLC, Tokyo (JP)

(21) Appl. No.: 19/576,889

(22) Filed: Mar. 24, 2026

(30) Foreign Application Priority Data
Apr. 21, 2025 (JP) 2025-069383

(51) Int. Cl. G11C 16/34; G11C 16/30; G11C 16/32

(52) U.S. Cl. CPC G11C 16/3495; G11C 16/30; G11C 16/32

(57) ABSTRACT

To reliably read written data regardless of the time that has passed since the data was written, each memory unit includes memory cells, and each memory cell holds a voltage corresponding to a value that is an element of the data. When reading the data from a memory unit, the controller sets a reference voltage that defines a voltage corresponding to a value based on the elapsed time from the write time when the data was written to the memory unit, and determines a value indicated by the voltage held in the memory cell using the reference voltage.

### CROSS-REFERENCE TO RELATED APPLICATION

The present application claims priority to Japanese Patent Application No. 2025-069383, filed Apr. 21, 2025, the content of which is incorporated herein by reference in its entirety.

### BACKGROUND

The present disclosure relates to a solid state memory, an information processing apparatus and a data processing method, and specifically relates to reading data stored in a solid state memory.

### Description of the Related Art

A solid state memory (solid state drive (SSD) ) is a memory that includes flash memory as a storage element. SSDs make it possible to read and write data faster than hard disk drives (HDDs) that have been widely used. For SSDs, data reading and writing is achieved through electrical operation, without any mechanical action, making it extremely quiet. A flash memory includes a plurality of memory cells, each of which includes a floating gate metal-oxide-semiconductor field-effect transistor (MOSFET).

A floating gate MOSFET has a two-layer gate structure with a source and drain on a substrate, with an insulating tunnel oxide film placed between them. The two-layer gate structure includes an insulating gate oxide film placed between a floating gate and a control gate. Data is written there by applying a voltage to the drain to store charge in the floating gate. Erasing of the data is achieved by releasing the charge from the floating gate. That is, a value constituting data is stored by the voltage generated in the floating gate of the memory cell.

Storage methods for NAND flash memory include single-level cell (SLC), multi-level cell (MLC), triple-level cell (TLC), quadrature-level cell (QLC) and the like. In the SLC, MLC, TLC, and QLC, two, four, eight, and 16 levels of threshold voltage Vth are used respectively to record 1-bit, 2-bit, 3-bit, and 4-bit values per cell. When reading data, the value corresponding to the held voltage is identified using a reference voltage V_{ref} of 1 level, 3 levels, 7 levels, and 15 levels in the SLC, MLC, TLC, and QLC, respectively. Each reference voltage V_{ref} is set to the midpoint between the threshold voltages Vₜₕ of two adjacent levels. The reference voltage V_{ref} may be called a program voltage. That is, the more voltage levels per cell they have, the higher density data can be recorded. However, the voltage range that represents the value of one level becomes narrower, so precise setting of the threshold voltage Vₜₕ is required.

In NAND flash memory, frequent data reading and writing cause stress-induced leakage current (SILC). This results in a failure to keep the voltage generated in the data cell, which may gradually decrease. The leakage current is mainly caused by the leakage of electrons from the floating gate and the leakage of electrons held in the oxide film. The leakage current is accelerated by the passage of time, deterioration of the data cell itself, a high temperature environment, and other factors. A drop in voltage can be a major cause of read errors. The leakage of charge injected into the oxide film can also cause the voltage value generated in the data cell to fall below the threshold voltage Vₜₕ. In particular, read errors are more pronounced in a multi-level cell NAND flash memory in which multiple levels of threshold voltage Vₜₕ are set.

[Patent Document 1] Japanese Unexamined Patent Application Publication No. 2013-141219

Then, existing SSDs change the reference voltage V_{ref} and retry reading data (Read Retry), thereby maintaining the integrity of the stored data and ensuring reliability. More specifically, in the writing process, data including an error detection code is stored in advance. In the reading process, the following steps are repeated until reading becomes successful: (1) setting a predetermined reference voltage V_{ref}; (2) decoding the data by identifying the voltage generated in each data cell using the set reference voltage V_{ref}; (3) determining whether the reading was successful or not based on the error detection code; and (4) if the reading fails, changing the reference voltage V_{ref} and returning to (2). However, the more severe the voltage drop that occurs in the data cell, the more iterations are required before a successful read is achieved. This results in a longer reading time.

### SUMMARY

A solid state memory device according to the first aspect of the present application includes: memory units; and a controller configured to control writing and reading of data for each of the memory units, each of the memory units including memory cells, each of the memory cells being configured to hold a voltage corresponding to a value that is an element of the data, and when reading the data from each of the memory units, the controller is configured to set a reference voltage that defines a voltage corresponding to the value on a basis of elapsed time from a write time when the data was written to each of the memory units, and determines the value indicated by the voltage held in each of the memory cells using the reference voltage.

In the above-described solid state memory device, the controller may be configured to set the reference voltage to be lower as the elapsed time increases.

In the above-described solid state memory device, when writing the data to each of the memory units, the controller may configured to record time at which the data is written as the write time.

In the above-described solid state memory device, the controller may be configured to refer to a preset look-up table that indicates a standard value for the reference voltage for each elapsed time from the write time, and identify the reference voltage that corresponds to the elapsed time.

In the above-described solid state memory device, when an error in the data read from each memory unit is detected, the controller may be configured to lower the reference voltage and determine the value indicated by the voltage held in each of the memory cells using the lowered reference voltage.

An information processing system according to the second aspect of the present application includes a host system and the solid state memory device, and when writing the data, the controller may be further configured to determine the write time based on time notified by the host system.

A data processing method according to the third aspect of the present disclosure is for a solid state memory device including: memory units; and a controller configured to control writing and reading of data for each of the memory units; each of the memory units including memory cells, the memory cells being configured to hold a voltage indicating a value that is an element of the data, the method comprises: when reading the data from each of the memory units, setting a reference voltage that defines a voltage corresponding to the value on a basis of elapsed time from a write time when the data was written to each of the memory units; and determining the value indicated by the voltage held in each of the memory cells using the reference voltage.

The above-described aspects of the present application enable reliable reading of written data regardless of the time that has passed since the data was written, and thus improves the performance during the reading process. Specifically, the reference voltage V_{ref} is set to a value corresponding to the time elapsed since the write time, and the read process is started using the set value. This improves the possibility of successful reading of the data and enables speedy reading process.

### BRIEF DESCRIPTION OF THE DRAWINGS

FIG. 1 is a schematic block diagram illustrating one example of the hardware configuration of the information processing apparatus according to the present embodiments.

FIG. 2 is a schematic block diagram illustrating one example of the functional configuration of the SSD according to the present embodiments.

FIG. 3 illustrates an example of the configuration of the memory chip according to this embodiments.

FIG. 4 illustrates one example of the data configuration of block head information according to the present embodiments.

FIG. 5 illustrates one example of the data configuration of block information according to the present embodiments.

FIG. 6 is a circuit diagram illustrating an example of the configuration of the memory chip according to this embodiments.

FIG. 7 describes an example of setting a reference voltage according to the present embodiments.

FIG. 8 illustrates an example of recording the write time according to this embodiments.

FIG. 9 illustrates an example of setting the reference voltage according to this embodiments.

FIG. 10 illustrates an example of a look-up table according to the present embodiments.

FIG. 11 is a flowchart of one example of the writing process according to the present embodiments.

FIG. 12 is a flowchart of one example of the reading process according to the present embodiments.

### DETAILED DESCRIPTION

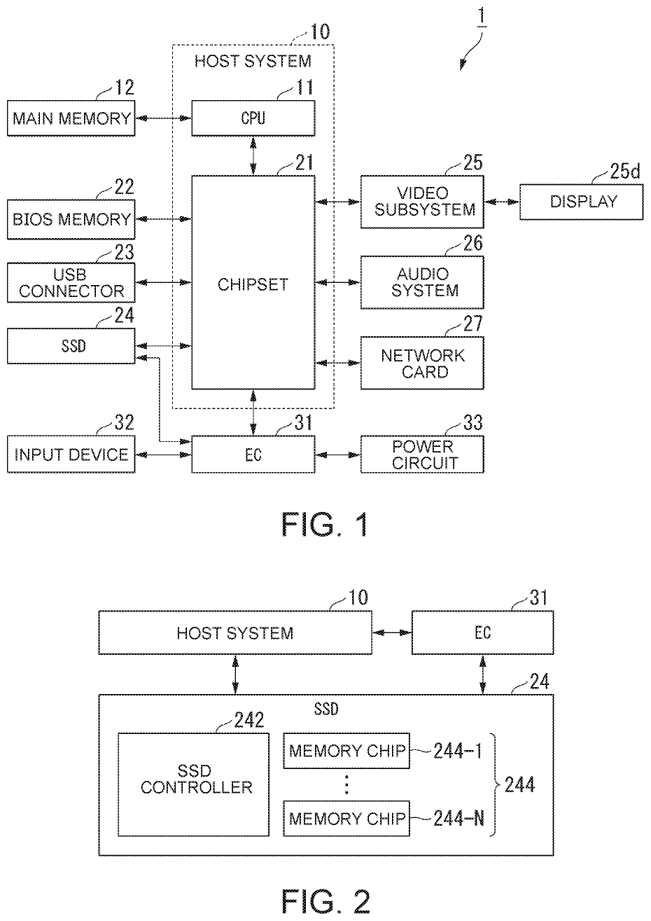

The following describes embodiments of the present application, with reference to the drawings. First, the following describes an example of the configuration of an information processing apparatus 1. FIG. 1 is a schematic block diagram illustrating one example of the hardware configuration of the information processing apparatus 1. The following describes the information processing apparatus 1 by way of an example of a laptop personal computer (PC), and the present disclosure is not limited to this example. The information processing apparatus 1 may be implemented in any form such as a desktop PC, a tablet terminal, or a multifunctional mobile phone (including a smart phone).

The information processing apparatus 1 includes a host system 10, a basic input output system (BIOS) memory 22, a universal serial bus (USB) connector 23, a solid state drive (SSD) (solid state memory) 24, a video subsystem 25, a display 25d, an audio system 26, a network card 27, an embedded controller (EC) 31, an input device 32, and a power circuit 33.

The host system 10 includes a central processing unit (CPU) 11, a main memory 12, and a chipset 21.

The CPU 11 is a processor that executes a program stored in the main memory 12 to execute various arithmetic processes and works with the main memory 12 and other hardware to realize and control the operations of various parts of the information processing apparatus 1. In this application, “executing a program” or “execution of a program” includes executing the processing directed by the commands described in the program.

The main memory 12 functions as a work area for the processing executed by the CPU 11. The main memory 12 temporarily or permanently stores programs executed by the CPU 11, data (including parameters) used in the processing executed by the CPU 11, and data generated by the processing of the CPU 11. The data stored in the main memory 12 may also include intermediate data that is generated by one process and may be used by a subsequent process. Examples of the programs that the CPU 11 executes include an operating system (OS), various types of drivers to operate hardware such as peripherals, various types of service/utility and application programs. The main memory 12 includes one or more dynamic random access memories (DRAMs).

The chipset 21 includes a bus controller for wired connection of various devices. The chipset 21 uses, for example, a PCIe (registered trademark) bus to connect to other devices. The chipset 21 enables connection of least the EC 31 and the SSD 24 using the PCIe (registered trademark) bus. The chipset 21 may use one or more methods other than the PCIe (registered trademark) for connection to other devices, including USB, serial AT attachment (ATA), serial peripheral interface (SPI) bus, peripheral component interconnect (PCI) bus, and low pin count (LPC) bus. The bus controller controls the input and output of data to and from the connected devices in accordance with the individual method.

The BIOS memory 22 includes a nonvolatile memory that stores system firmware. The nonvolatile memory includes electrically erasable programmable read only memory (EEPROM) and flash ROM. The system firmware is a program that is involved in the operation of the entire computer system and provides an interface between the hardware and various programs executed in the host device. An example of the system firmware is a BIOS. In this application, such system firmware may be collectively referred to as “BIOS.”

The USB connector 23 is an interface to detachably connect peripherals using USB. The USB connector 23 is fixedly provided in the chassis of the information processing apparatus 1.

The SSD 24 is an auxiliary memory that includes a rewritable nonvolatile memory and stores various types of data. The SSD 24 is capable of writing new data, reading stored data, or erasing already stored data in accordance with commands sent from the host system 10. The SSD 24 may include programs executed by the host system 10, such as an OS, drivers, services/utilities, and application programs.

The video subsystem 25 executes processing related to image display (drawing) under the control of the CPU 11. The video subsystem 25 is a processor that includes a video memory and has functions related to image display under the control of the CPU 11. The video subsystem 25 processes a drawing command from the CPU 11, and writes the obtained drawing information in the video memory. The video subsystem 25 reads the newly written drawing information from the video memory, and outputs the read drawing information to the display 25d as drawing data (display data).

The display 25d displays a display screen based on the drawing data (display data) output from the video subsystem 25. In one example, the display 25d is a liquid crystal display.

The audio system 26 is a device that enables input/output, recording, and playback of audio data.

The network card 27 connects to a network and enables data communication to be performed either wired or wirelessly. The network card 27 may be able to connect to other devices directly using a wireless local area network (LAN) or also via another network.

The EC 31 is a microcomputer that monitors and controls various devices (e.g., peripherals and sensors), irrespective of the operating state (operating mode) of the information processing apparatus 1. In one example, the EC 31 is configured as a one-chip microcomputer (not illustrated) including a CPU, a ROM, a RAM, a multi-channel analog to digital (A/D) input terminal, a digital to analog (D/A) output terminal, a timer, and a digital input/output terminal. In one example, the input device 32 and the power circuit 33 are connected to the digital input/output terminal. The SSD 24 is connected to the EC 31 in accordance with, for example, the I3C (registered trademark) standard.

The EC 31 executes predetermined firmware that is separate from the system firmware and exerts its functions. The EC 31 has temperature control and power management functions. The temperature control function is of acquiring temperature data from the SSD 24 and of controlling the operation of a heat dissipation mechanism (e.g., a heat dissipation fan (not illustrated) ) in the information processing apparatus 1 in accordance with the acquired temperature data. The power management function is of controlling the power circuit 33 to supply power that is to be consumed by each part of the information processing apparatus 1. In one example, the EC 31 controls the power supplied to the CPU 11 and other devices.

The input device 32 receives an operation by a user, and outputs an operation signal corresponding to the received operation to the EC 31. The operation signal indicates various types of information or commands. In one example, the input device 32 may be any of a keyboard, a touchpad, a pointing device and other similar devices.

The power circuit 33 converts a DC voltage supplied from the AC/DC (alternate current/direct current) adapter or from the battery unit into an operating voltage to operate each of the devices in the information processing apparatus 1. The power circuit 33 supplies the power having the operating voltage to each device. one example, the power circuit 33 includes a DC/DC converter and a charge-discharge unit, in addition to the AC/DC adaptor and the battery unit. The power circuit 33 operates under the control by the EC 31.

Note that to realize its functions, the host system 10 may cause to write data to the SSD 24, read data stored in the SSD 24, or erase data stored in the SSD 24.

When writing data to the SSD 24, the host system 10 issues a write command involving the data to be written (write target data), and outputs the issued write command to the SSD 24.

When reading data from the SSD 24, the host system 10 issues a read command indicating the data to be read (read target data), and outputs the issued read command to the SSD 24. The host system 10 obtains, from the SSD 24, the read target data that is specified by the read command as a response to the read command.

When erasing data stored in the SSD 24, the host system 10 outputs, to the SSD 24, an erase command indicating the data to be erased.

Next, the following describes an example of the functional configuration of the SSD 24. FIG. 2 is a block diagram schematically illustrating one example of the functional configuration of the SSD 24.

The SSD 24 is connected to the host system 10 and to the EC 31.

The SSD 24 includes an SSD controller 242, a type of processor, and N memory chips 244 (N is an integer equal to or greater than 2, typically 4 to 128). In FIG. 2, the individual memory chips 244 are distinguished by sub-numbers like −1 assigned thereto, as in 244-1. These memory chips 244 may also be called dies. The SSD controller 242 and the N memory chips 244 are placed on the surface of a common substrate so as not to overlap each other.

Each memory chip 244 includes a plurality of memory cells. The memory cells may be based on any of the methods, such as the floating gate method and the charge trap method. Each memory cell enables one or more bits of information to be stored. The memory cells may be any of SLC, MLC, TLC, QLC, and others.

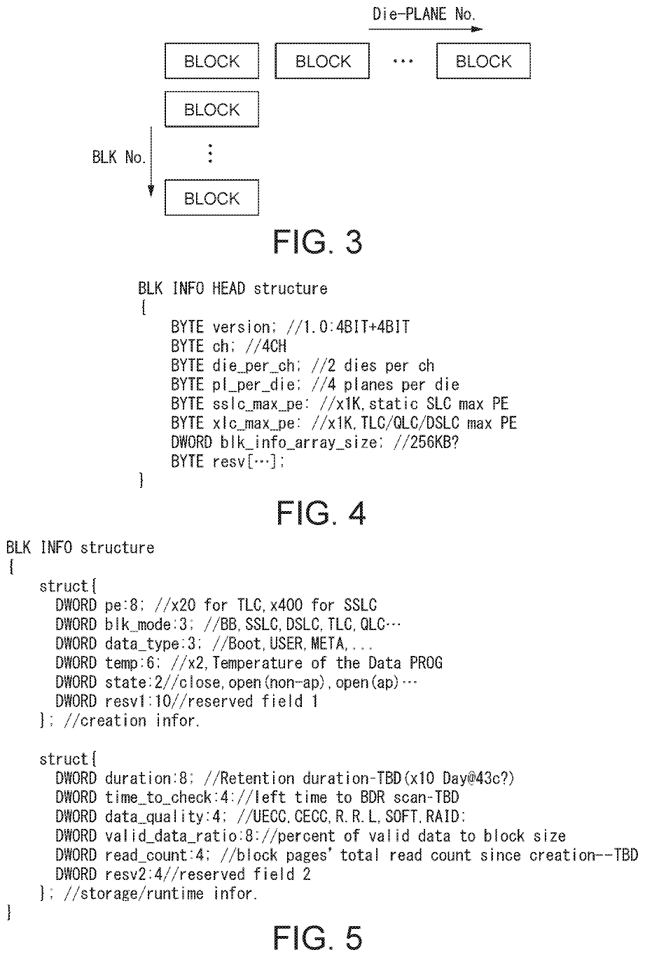

The N memory chips 244 configure the storage area of the SSD 24. Each memory chip 244 includes a plurality of data blocks (they may be simply referred to as “blocks” in this application). FIG. 3 illustrates an example, in which each memory chip 244 has multiple planes, and each plane has multiple blocks. Each plane is identified by a die-plane number. Each block is identified by a block number (BLK No.). Data is written or read in units of pages. Data per page is erased in units of blocks. In other words, each block corresponds to a memory unit for storing data.

The SSD controller 242 manages whether or not data is stored in each block, and the write time of the data for each page in the blocks where the data is stored. Each page is identifiable using the memory address. The storage area of the SSD 24 stores one block head information. This block header information describes the specifications of the entire storage area of the SSD 24 and the specifications common to the blocks. The block head information (BLK INFO HEAD structure) illustrated in FIG. 4 describes the version, channel (ch), the number of dies per channel (die_per_ch), the number of planes per die (pl_per_die), and maximum rewrite life (sslc_max_pe, xlc_max_pe). The rewrite life tends to be shorter for memory methods with a larger number of bits per cell.

A piece of block information is stored for each block. The block information (BLK INFO) illustrated in FIG. 5 describes the usage status and data recording status of each block. It describes, as the usage status for each block, the rewrite life (pe), storage method (blk_mode), data type, temperature at the time of writing (temp), and access state (state). It describes, as information on the data recording state, data retention time (duration), time until the next check disk (time_to_check), data quality (data_quality), valid data ratio (valid_data_ratio), and the number of reads after writing (read_count). The SSD controller 242 updates the block information based on the access content specified by a command sent from the host system 10 each time it accesses the block.

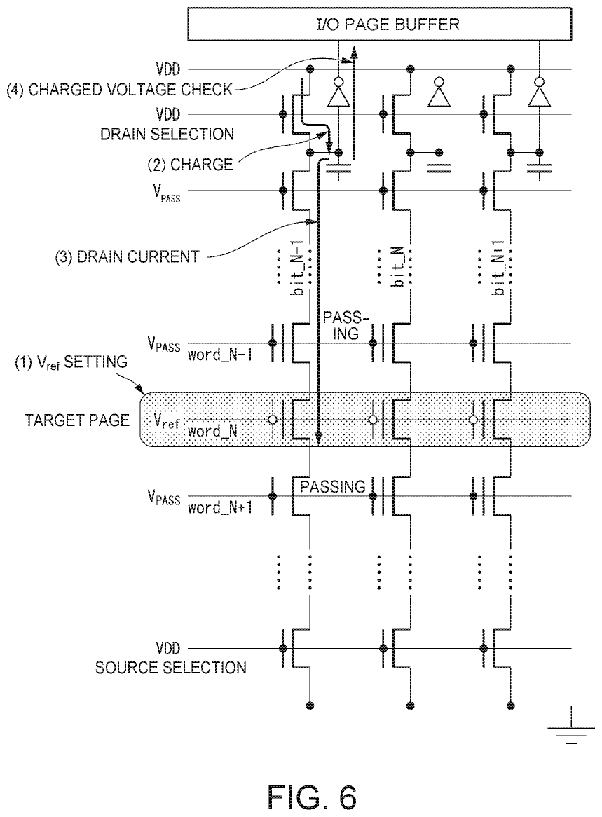

Next, the following describes one example of the configuration of the memory chip 244. FIG. 6 is a circuit diagram illustrating an example of the configuration of the memory chip 244. The memory chip 244 illustrated in FIG. 6 is configured as a NAND flash memory. This example describes the case where the storage method of each memory cell is SLC.

The memory chip 244 includes a large number of memory cells arranged two-dimensionally on a substrate for each block. Each block has a bit line in each column. Each row of the block is called a word line and corresponds to a page. Each column of the block corresponds to an individual bit. A bit line is formed by connecting a plurality of memory cells in series. One end of the bit line is connected to a power supply via a bit-line selection transistor, and one end of a capacitor is connected to the other end of the bit line selection transistor and one end of the memory cell in the first row. One end of each capacitor is connected to the I/O page buffer via an inverting circuit. The I/O page buffer is included in the SSD controller 242 and temporarily stores write target data or read target data. The other end of the bit line is connected to the reference potential point via a ground selection transistor. The power supply voltage V_{DD} is applied to the control gate of the ground selection transistor.

Referring next to FIG. 6, the following describes a method for writing data. The SSD controller 242 applies the threshold voltage Vth corresponding to the individual values constituting the write target data among the memory cells in the target page to the memory cells located in the columns where the values should be recorded. The memory cell storage method is SLC, and thus a single level of threshold voltage Vₜₕ and reference voltage V_{ref} are applied. The reference voltage V_{ref} is used to determine whether the written value based on the voltage V (hereinafter this may be referred to as “holding voltage V”) generated in the memory cell is “1” or “0”. A value lower than the threshold voltage Vₜₕ corresponding to the value “1” is set as the reference voltage V_{ref}.

Specifically, the SSD controller 242 operates as follows when writing data. (1) A reference voltage V_{ref} is set to the control gates of the memory cells in each column of the target page.

(2) A power supply voltage V_{DD} is set to the control gate of the bit line select transistor for each column corresponding to a bit to be written with a value “1”. This connects one end of the capacitor to a power source, causing the one end of the capacitor to be charged. (3) For each column, a power supply voltage V_{DD} is set to the control gates of memory cells in each row other than the target page, so that a drain current flows from the capacitor to the memory cells of the target page to charge them. (4) The voltage generated at one end of the capacitor in each column is detected. The SSD controller 242 continues to charge the memory cells until the voltage detected from each column reaches the threshold voltage Vₜₕ that exceeds the set reference voltage V_{ref}.

When the SSD controller 242 has finished writing the data, it stores the write time when the writing was executed to the target page to be written so that the write time is included in the block information.

When reading data, the SSD controller 242 detects the holding voltage V of each column in the page to be read. The SSD controller 242 compares the detected holding voltage V with the reference voltage V_{ref} to identify the value corresponding to the holding voltage V. That is, the reference voltage V_{ref} corresponds to a threshold value for defining the value indicated by the holding voltage V.

When the memory cell storage method is SLC, a single level of reference voltage V_{ref} is used to identify the value. If the holding voltage V is lower than the reference voltage V_{ref}, the SSD controller 242 determines that the value indicated by the holding voltage V is “0.”

The SSD controller 242 is able to read and write data from and to memory cells that can store multi-bit values, such as MCL, using the same procedure as above. Note that a threshold voltage V_{th,n} and a reference voltage V_{ref,n} corresponding to each value n are set (see FIG. 9).

The threshold voltage Vth, n for the value n is set to an intermediate value between the reference voltage V_{ref,n} for the value n and the reference voltage V_{ref,n+1} for the value n+1, which is one-level larger. When writing data, the SSD controller 242 may apply a threshold voltage V_{th,n} corresponding to the value n that constitutes the write target data.

When reading data, the SSD controller 242 detects the holding voltage V for each memory cell in the target page and compares the detected holding voltage V with the reference voltage V_{ref,n} of each level. If the holding voltage V is greater than or equal to the reference voltage V_{ref,n} corresponding to a certain level of value n and is less than the reference voltage V_{ref,n+1} corresponding to the one-level higher value n+1, the SSD controller 242 determines that the value indicated by the holding voltage V is n.

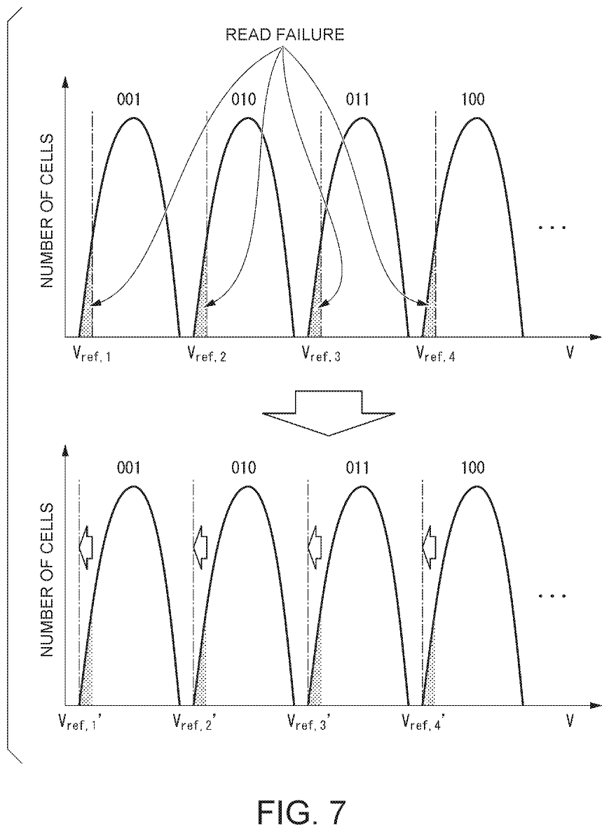

The holding voltage V is equal to the threshold voltage Vth at the beginning of data writing, but tends to gradually decrease over time. If the holding voltage V drops below the reference voltage V_{ref,n} corresponding to the written value n, a read error may occur because the value identified by the SSD controller 242 from the holding voltage V detected at that time is the value n−1 that is smaller than the written value n. In general, the holding voltage of a memory cell to which a threshold voltage corresponding to a specific value is applied may vary from one memory cell to another, due to individual variations in memory cells and the frequency of use. Therefore, the holding voltage V varies for each value. The upper part of FIG. 7 illustrates the distribution of the number of memory cells versus the holding voltage V for each of the values 001, 010, 011, and 100. The holding voltage V of some memory cells is below the reference voltages V_{ref,1}, V_{ref,2}, V_{ref,3}, and V_{ref,4} for the values 001, 010, 011, and 100, respectively, and therefore reading of the written values fails.

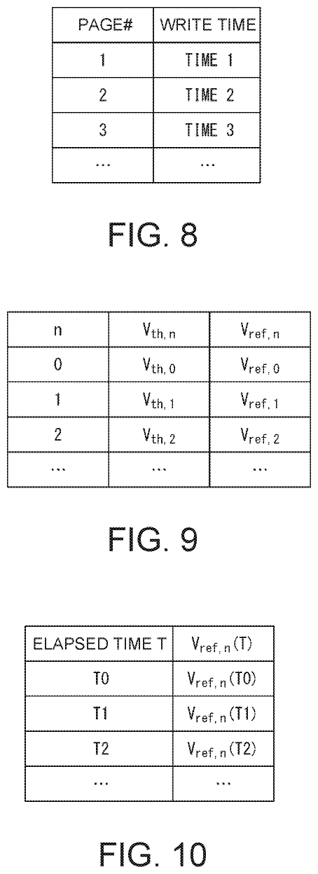

Then, when writing data, the SSD controller 242 records the time of writing for each page as a write time. FIG. 8 illustrates the example in which the write times for pages 1, 2, and 3 are recorded as TIME 1, TIME 2, and TIME 3, respectively. These write times may be recorded as part of the block information of the block belonging to each page, or may be recorded separately from the block information.

When reading data, the SSD controller 242 identifies the time that has elapsed since the write time recorded in the page to be read, and adjusts the reference voltage V_{ref,n} so that it decreases based on the elapsed time. The lower part of FIG. 7 illustrates the example in which, for the values 001, 010, 011, and 100, reference voltages V_{ref,1′}, V_{ref,2′}, V_{ref,3′}, and V_{ref,4′} set are adjusted to be lower than the reference voltages V_{ref,1}, V_{ref,2}, V_{ref,3}, and V_{ref,4} at the time of writing, respectively. The reference voltages V_{ref,1′}, V_{ref,2′}, V_{ref,3′}, and V_{ref,4′} are lower than the distribution of holding voltages V of the memory cells for the values 001, 010, 011, and 100, respectively. Therefore, no memory cells fall below the reference voltages V_{ref,1′}, V_{ref,2′}, V_{ref,3′}, and V_{ref,4′} for the values 001, 010, 011, and 100, respectively, which eliminates detection failures.

A look-up table may be set beforehand that indicates the standard value of the reference voltage V_{ref,n} for each elapsed time, and the SSD controller 242 may identify the standard value of the reference voltage V_{ref,n} corresponding to the memory cell storage method based on the elapsed time, and use this standard value to identify the value from the holding voltage V. In the look-up table illustrated in FIG. 10, the standard values of the reference voltages are written as V_{ref,n} (T0), V_{ref,n} (T1), and V_{ref,n} (T2) for elapsed times T0, T1, and T2, respectively. The reference voltages are set so that V_{ref,n} (T0), V_{ref,n} (T1), and V_{ref,n} (T2) decrease in this order, with V_{ref,n} (T0) being the highest. FIG. 10 illustrates a look-up table showing the reference voltage V_{ref,n} for the value n, but the SSD controller 242 may be configured to set a look-up table for each value.

The SSD controller 242 identifies the reference voltage as V_{ref,n} (T0) if the elapsed time at that time is equal to or less than T0, identifies the reference voltage as V_{ref,n} (T1) if the elapsed time at that time is longer than T0 but equal to or less than T1, and identifies the reference voltage as V_{ref,n} (T2) if the elapsed time at that time is longer than T1 but equal to or less than T2. Instead of the look-up table, the SSD controller 242 may be provided with a function in advance so that the function is configured to receive, as an input, an elapsed time and output a reference voltage. The SSD controller 242 uses this configured function to calculate a reference voltage corresponding to the elapsed time.

The SSD controller 242 may use the time measured by itself or the EC 31 as the write time or read time, or may obtain a timestamp indicating the time measured by the host system 10 and refer to the obtained timestamp. The SSD controller 242 may use a timestamp attached to the write command or read command. In this case, the host system 10 adds a timestamp indicating the time at which the write command or the read command was issued to each command, and outputs the command to the SSD 24.

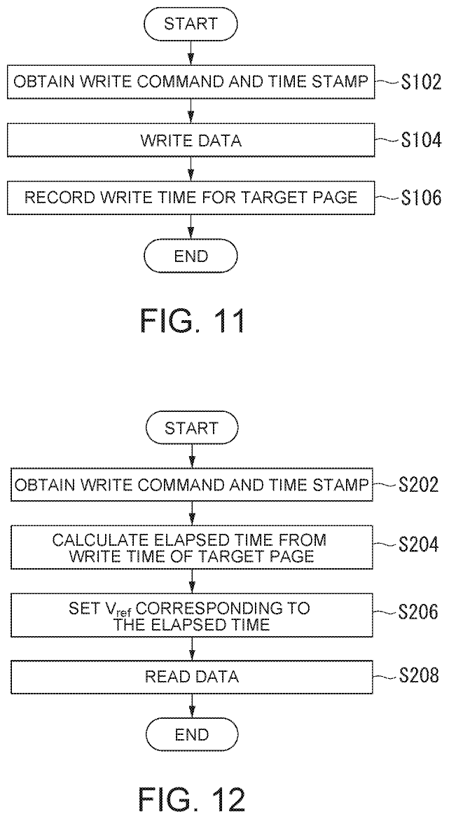

Next, the following describes an example of the writing process. FIG. 11 is a flowchart of one example of the writing process.

(Step S102) The SSD controller 242 waits for a write command from the host system 10. When receiving a write command from the host system 10, the SSD controller 242 identifies the write target data and write target address specified in the input write command, and reads the timestamp added to the write command.

(Step S104) The SSD controller 242 writes the write target data to the write target page indicated by the identified write target address. At this time, the SSD controller 242 applies, for each value constituting the data, the threshold voltage Vth corresponding to the value to the memory cell in the write target page to which the value is to be written.

(Step S106) The SSD controller 242 records, as the write time, the time indicated by the timestamp read for the write target page. The process in FIG. 11 then ends.

Next, the following describes an example of the reading process. FIG. 12 is a flowchart of one example of the reading process.

(Step S202) The SSD controller 242 waits for a read command from the host system 10. When receiving a read command from the host system 10, the SSD controller 242 identifies the read target data and read target address specified in the input read command, and reads the timestamp added to the read command.

(Step S204) The SSD controller 242 reads the write time of the read target page indicated by the identified read target address and identifies the time indicated by the time stamp as the read time. The SSD controller 242 calculates the elapsed time from the write time to the read time.

(Step S206) The SSD controller 242 refers to a preset look-up table and identifies the reference voltage V_{ref} that corresponds to the calculated elapsed time.

(Step S208) The SSD controller 242 detects the holding voltage V for each memory cell in the read target page, identifies a value corresponding to the detected holding voltage V by comparing with the identified reference voltage V_{ref}, and converts it into data indicating the identified value for each memory cell. The SSD controller 242 outputs the data (as read target data) obtained by the conversion to the host system 10 as a response to the read command. The process in FIG. 12 then ends.

In the process of FIG. 11, the SSD controller 242 may store the write target data in the write target page together with an error detection code generated using a predetermined error detection method. In this case, in the process of FIG. 12, the SSD controller 242 may use the error detection method to determine whether or not there is an error in the data obtained from the holding voltage V of each memory cell in the read target page, and if it is determined that there is no error, the SSD controller 242 may determine that the reading was successful and end the process of FIG. 12. If it is determined that there is an error, the SSD controller 242 may determine that the reading has failed and repeat the following processes (i) and (ii) until it is determined that there is no error or until the number of repetitions reaches a predetermined limit: if the error is not resolved even after the number of repetitions reaches the limit, the SSD controller 242 determines that reading fails and notifies the host system 10 as such. (i) The reference voltage V_{ref} is decreased by a predetermined adjustment amount; and (ii) the presence or absence of error is determined about the data obtained by converting the holding voltage V of each memory cell in the read target page using the adjusted reference voltage V_{ref}. Also in this case, the initial reference voltage V_{ref} is adjusted according to the time elapsed from the write time, thus reducing the number of repetitions until a successful read or a read failure.

The processing in FIG. 11 and FIG. 12 is based on the example where SLC is used as the storage method for memory cells, but the present disclosure is not limited to this. The processing may be applied to a storage method that allows multiple-bit values to be recorded. This storage method may also be applied to MLC, TLC, QLC, and other methods that allow recording of multiple-bit values. In that case, when reading data, the SSD controller 242 may adjust the reference voltage V_{ref,n} at of each level according to the time elapsed from the write time, and then use the adjusted reference voltage V_{ref,n} to identify the value indicated by the holding voltage V detected from the memory cell.

The above example describes the case in which the SSD 24 is built into the information processing apparatus 1, but the present disclosure is not limited to this. The SSD 24 may be configured as a storage device separate from the information processing apparatus 1, as long as it can connect to the information processing apparatus 1 so as to be able to send and receive various data.

As described above, the solid state memory (e.g., SSD 24) includes a plurality of memory units (e.g., pages) and a controller (e. g., SSD controller 242) that controls the writing and reading of data for each memory unit. Each memory unit includes a plurality of memory cells, and each memory cell holds a voltage corresponding to a value that is an element of data. When reading the data from a memory unit, the controller sets a reference voltage that defines a voltage corresponding to a value based on the elapsed time from the write time when the data was written to the memory unit, and determines a value indicated by the voltage (e.g., a holding voltage) held in the memory cell using the set reference voltage.

The controller may set the reference voltage to be lower as the elapsed time increases.

With this configuration, the reference voltage is determined based on the time elapsed from the write time to the read time. Taking into consideration the change characteristics of the voltage held in the memory cell over time, the voltage is converted into a value constituting data. This allows the data written in the solid state memory to be read reliably regardless of the time that has passed since the data was written. This reduces the reading time because it avoids or suppresses the need for re-reading accompanied by adjustment of the reference voltage.

When writing data to a memory unit, the controller may record the time at which the data is written as the write time.

The controller may refer to a preset look-up table that indicates the standard value for reference voltage for each elapsed time from the write time, and identify the reference voltage that corresponds to the elapsed time from the write time when data was written to the memory cell in the read target page.

When an error in the data read from the memory unit is detected, the controller may lower the reference voltage and use the lowered reference voltage to determine a value indicated by the voltage held in the memory cell in the read target page.

The information processing apparatus 1 includes the host system 10 and the SSD 24 mentioned above, and when writing write target data, the controller may determine the write time based on the time notified by the host system 10.

A data processing method is for a solid state memory including: a plurality of memory units; and a controller configured to control writing and reading of data for each of the memory units; each memory unit including a plurality of memory cells, the plurality of memory cells being configured to each hold a voltage indicating a value that is an element of the data, the method includes the following steps by a controller: setting a reference voltage that defines a voltage corresponding to the value on a basis of elapsed time from a write time when the data was written to the memory unit; determining a value indicated by the voltage (e.g., holding voltage) held in the memory cell using the set reference voltage; and setting a reference voltage that defines a voltage corresponding to a value based on the elapsed time from the write time when the data was written to the memory unit, and determining a value indicated by the voltage (e. g., a holding voltage) held in the memory cell using the set reference voltage.

That is the specific descriptions on the embodiments of the present disclosure, with reference to the drawings. The specific configuration of the present disclosure is not limited to the above-described embodiments, and also includes design modifications or the like within the scope of the present disclosure. The configurations described in the above embodiments can be combined freely.

Although the disclosure has been described with respect to only a limited number of embodiments, those skilled in the art, having benefit of this disclosure, will appreciate that various other embodiments may be devised without departing from the scope of the present disclosure. Accordingly, the scope of the disclosure should be limited only by the attached claims.

### DESCRIPTION OF SYMBOLS

1 information processing apparatus
10 host system
11 CPU
12 main memory
21 chipset
22 BIOS memory
23 USB connector
24 SSD
242 SSD controller
244 (244-1 to 244-N) memory chip
25 video subsystem
25d display
26 audio system
27 network card
31 EC
32 input device
33 power circuit

What is claimed is:

1. A solid state memory device comprising:
memory units; and
a controller configured to control writing and reading of data for each of the memory units, each of the memory units including memory cells,
each of the memory cells configured to hold a voltage corresponding to a value that is an element of the data, wherein
the controller is configured to,
when reading the data from each of the memory units,
set a reference voltage that defines a voltage corresponding to the value on a basis of elapsed time from a write time when the data was written to each of the memory units, and
determine the value indicated by the voltage held in each of the memory cells using the reference voltage.

2. The solid state memory device according to claim 1, wherein the controller is configured to
set the reference voltage to be lower as the elapsed time increases.

3. The solid state memory device according to claim 1, wherein the controller is configured to,
when writing the data to each of the memory units, record time at which the data is written as the write time.

4. The solid state memory device according to claim 1, wherein the controller is configured to,
refer to a preset look-up table that indicates a standard value for the reference voltage for each elapsed time from the write time, and
identify the reference voltage that corresponds to the elapsed time.

5. The solid state memory device according to claim 1, wherein the controller is configured to,
when an error in the data read from each of the memory units is detected,
lower the reference voltage, and
determine the value indicated by the voltage held in each of the memory cells using the lower reference voltage.

6. An information processing system comprising: a host system; and
the solid state memory device according to claim 1, wherein
the controller is further configured to, when writing the data, determine the write time based on time notified from the host system.

7. A data processing method for a solid state memory device including: memory units; and
a controller configured to control writing and reading of data for each of the memory units; each of the memory units including memory cells,
each of the memory cells configured to hold a voltage indicating a value that is an element of the data, the data processing method comprising:
when reading the data from each of the memory units,
setting a reference voltage that defines a voltage corresponding to the value on a basis of elapsed time from a write time when the data was written to each of the memory units; and
determining the value indicated by the voltage held in each of the memory cells using the reference voltage.
